(19) United States
(12) Patent Application Publication
(10) Pub. No.: US 2026/0328604 A1
(43) Pub. Date: Oct. 22, 2026

(54) MULTIPHASE GAS FLOW METERING

(71) Applicant: Saudi Arabian Oil Company, Dhahran (SA)

(72) Inventors: Oshokhayamhe Ilamah, Dhahran (SA); Aamir Badr, Dhahran (SA)

(21) Appl. No.: 19/183,652

(22) Filed: Apr. 18, 2025

(51) Int. Cl. G01F 1/74; E21B 41/00; E21B 49/08; G01F 1/44; G06F 30/28

(52) U.S. Cl. CPC G01F 1/74; E21B 41/00; E21B 49/08; G01F 1/44; G06F 30/28; E21B 2200/20

(57) ABSTRACT

Systems and methods for calculating a flow rate of a multiphase wellstream flowing through a Venturi meter. The method includes predicting a fluid composition of the wellstream via reservoir simulation using a compositional reservoir simulation model and an Equation of State (EOS). A PVT simulation system simulates one or more PVT experiments using the predicted composition and the EOS to generate a dataset of fluid properties associated with pressure and temperature values. A plurality of regression response models is trained using a subset of the dataset, each model configured to predict a respective fluid property based on pressure and temperature. The trained regression models are used to generate predicted fluid properties using real-time pressure and temperature data of the multiphase wellstream flowing through the Venturi meter. A flow rate is then calculated based on the predicted properties, and one or more actions are performed based on the result.

### TECHNICAL FIELD

This disclosure generally relates to a system and method for multiphase gas flow metering.

### BACKGROUND

In oil and gas field operations, accurate wellstream metering is crucial for well performance monitoring, well modelling, production allocation and reservoir management. Due to their simplicity and low costs, Venturi meters are widely used to meter oil and gas wellstreams. For multiphase wellstreams, the flow rate measured using the Venturi meter depends on the state-dependent pressure, volume, temperature (PVT) parameters, such as gas density, condensate density, and condensate mass fraction. However, the PVT parameters vary depending on Venturi pressure and temperature conditions as well as the fluid composition of a wellstream.

### SUMMARY

This disclosure describes systems and methods for predicting the state-dependent fluid properties of multiphase wellstreams to calculate the flowrate of the multiphase wellstream.

The method includes obtaining a history-matched compositional reservoir simulation model and a tuned Equation of State (EOS) of the reservoir fluid based on previously collected PVT fluid samples and laboratory experiments. The method further includes predicting a fluid composition of a wellstream that is representative of the operating conditions by performing compositional reservoir simulations using the history-matched compositional reservoir simulation model and a tuned EOS. The determined wellstream composition is provided to a PVT simulation system, which uses the tuned EOS to simulate PVT experiments for all possible combinations of pressure and temperature values within the expected range of Venturi pressure and temperature conditions. The fluid properties, including PVT parameter values, such as gas density (e.g., p_{g}), condensate density (e.g., p_{c}), and condensate mass fraction (e.g., x_{c}), resulting from the simulated PVT experiments are stored in a dataset in association with the corresponding pressure and temperature values. The dataset is used to develop respective regression response models for each PVT parameter. Each of the respective regression models are trained on a first subset of the dataset, and subsequently validated on a second subset of the dataset. The validated regression models are used to calculate mass or volume flow rates for the pressure and temperature conditions corresponding to the desired operation conditions. The method further includes performing an action based on the calculated flow rate, such as executing reactive well control, assessing well performance, and allocating reservoir production.

Implementations of the systems and methods of this disclosure can provide various technical benefits. Multiphase wellstream metering can be a complex and operationally challenging task, particularly in systems where fluid properties vary with time and operating conditions. Accurate flow rate measurement of the wellstream depends on a reliable approach to predicting the PVT parameters. Unlike approaches that rely on routine wellstream fluid sampling and laboratory testing, the method enables accurate multiphase well flow metering and minimizes the need for additional fluid sampling and laboratory testing by utilizing existing reservoir fluid model developed from earlier fluid samples to predict current fluid properties, considering the current state of the reservoir as well as the surface measurement conditions. Consequently, the method avoids the costs and time associated with routine fluid sampling.

Additionally, the method eliminates errors due to fluid sampling challenges by using an EOS established from earlier pre-depletion fluid samples rather than routine post-production samples which are far more likely to be contaminated or unrepresentative. The method simulates the PVT experiments on a computing system, allowing significantly more simulated experiments to be performed, resulting in more datapoints for fitting and validating the regression response models. As a result, the method may also be used for fields with rapidly changing wellstream fluid compositions, for example, due to partial mixing and reproduction of injected fluids in gas cycling and underground gas storage operations.

The details of one or more implementations of these systems and methods are set forth in the accompanying drawings and the description below. Other features, objects, and advantages of these systems and methods will be apparent from the description and drawings, and from the claims.

### DESCRIPTION OF DRAWINGS

FIG. 1 is a schematic view illustrating an example well system for wellstream production and metering.

FIG. 2 is a flowchart for an example method for calculating a flow rate of a multiphase wellstream through a Venturi meter using a plurality of regression response models.

FIG. 3A is a flowchart that represents an example PVT experiment executed by a PVT simulation system to generate a dataset of fluid properties under various operating conditions.

FIG. 3B is a table that represents example gas density values obtained from simulated PVT experiments.

FIG. 3C is a plot that illustrates the validation of a gas density regression response model against simulated PVT experiment results.

FIG. 4 is a block diagram illustrating an example computer system used to provide computational functionalities associated with described algorithms, methods, functions, processes, flows, and procedures according to some implementations of the present disclosure.

Like reference symbols in the various drawings indicate like elements.

### DETAILED DESCRIPTION

This disclosure describes systems and methods for predicting the state-dependent fluid properties of multiphase wellstreams to calculate the flowrate of the multiphase wellstream. The method includes obtaining a history-matched compositional reservoir simulation model and a tuned EOS of the reservoir fluid based on previously collected PVT fluid samples and laboratory experiments. The method further includes predicting a fluid composition of a wellstream that is representative of the operating conditions by performing compositional reservoir simulations using the history-matched compositional reservoir simulation model and a tuned EOS. The determined wellstream composition is provided to a PVT simulation system, which uses the tuned EOS to simulate PVT experiments for all possible combinations of pressure and temperature values within the expected range of Venturi pressure and temperature conditions. The fluid properties, including PVT parameter values, such as gas density (e.g., p_{g}), condensate density (e.g., p_{c}), and condensate mass fraction (e.g., x_{c}), resulting from the simulated PVT experiments are stored in a dataset in association with the corresponding pressure and temperature values. The dataset is used to develop respective regression response models for each PVT parameter. Each of the respective regression models are trained on a first subset of the dataset, and subsequently validated on a second subset of the dataset. The validated regression models are used to calculate mass or volume flow rates for the pressure and temperature conditions corresponding to the desired operation conditions. The method further includes performing an action based on the calculated flow rate, such as executing reactive well control, assessing well performance, and allocating reservoir production.

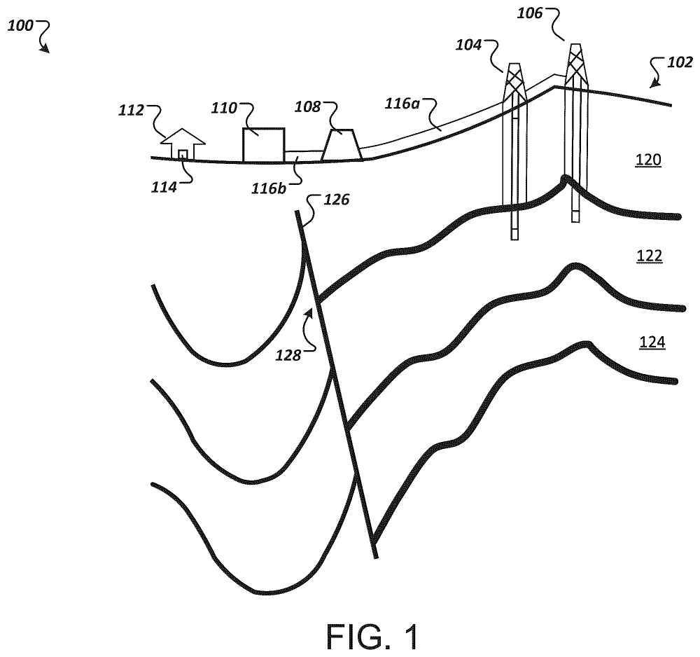

FIG. 1 is a schematic view illustrating an example well system 100 for wellstream production and metering. The well system 100 is configured to extract a reservoir fluid from a subsurface formation 102 and to measure flow characteristics of the resulting wellstream, which comprises a fluid mixture including gas, condensate, and water. The well system 100 includes an injection well 104, a production well 106, a Venturi meter system 108, a processing facility 110, and a control center 112 that includes a computing system 114.

The subsurface formation 102 includes a layer of impermeable cap rocks 120 at the surface. Facies underlying the impermeable cap rocks 120 include layers 122 and 124. A fault line 126 extends across the layer 122 and the layer 124. Oil and gas tend to rise through permeable reservoir rock until further upward migration is blocked, for example, by the layer of impermeable cap rock 120. Structural features within the subsurface formation 102 may trap hydrocarbons by limiting their upward movement. For example, as shown in FIG. 1, a fault trap 128 is formed where the fault line 126 displaces reservoir layers and traps hydrocarbons against impermeable material, such as clay, along the fault boundary.

The injection well 104 and the production well 106 extend into layer 122 of the subsurface formation 102 and are configured to facilitate the recovery of reservoir fluids from layer 122. For example, injection well 104 may be configured to inject water or carbon dioxide through the injection well 104 to increase the production of (the wellstream) through the production well 106. The produced wellstream flows through a surface pipeline 116, which directs it to a Venturi meter system 108 for flow metering, and subsequently to a processing facility 110 for separation and treatment.

The Venturi meter system 108 may be positioned on the surface pipeline 116, upstream of the processing facility 110. The Venturi meter system 108 is configured to measure the flowrate of a multiphase wellstream under prevailing operating conditions. The Venturi meter system 108 includes a Venturi meter, one or more sensors, and a controller. The Venturi meter serves as a conjunction between two surface pipelines 116a, 116b. The Venturi meter is configured to receive the wellstream fluid from surface pipe 116a, meter the flow of the wellstream, and pass the wellstream downstream through to surface pipeline 116b. The one or more sensors may include pressure sensors and temperature sensors positioned at various locations along the body of the Venturi meter. The controller collects pressure and temperature data via the one or more sensors on the Venturi meter and transmits the sensor data to computing system 114 for analysis. The one or more sensors may be communicatively coupled to the controller via wired (e.g., ethernet, serial communication link, USB) or wireless connections (e.g., Wi-Fi, Bluetooth, cellular).

The computing system 114 in the control center 112 can be configured to determine the flow rate of a wellstream to perform reactive well control, assess well performance, and assess and allocate reservoir production. In some embodiments, the computing system 114 implement a compositional reservoir simulation system configured to generate a compositional reservoir simulation model. The compositional reservoir simulation model is configured to predict the fluid composition of the wellstream under certain operational conditions. The computing system 114 may further implement a PVT simulation system that is configured to determine the fluid properties of the wellstream based on the fluid composition.

The computing system 114 in the control center 112 can be further configured to receive real-time sensor data captured by the one or more sensors from the controller. The computing system 114 may be communicatively coupled to the controller via wired (e.g., ethernet, serial communication link, USB) or wireless connections (e.g., Wi-Fi, Bluetooth, cellular). The computing system 114 may implement a plurality of trained regression response models configured to analyze the real-time sensor data to generate predicted fluid properties of the wellstream. The computing system 114 is further configured to calculate the flow rate of the wellstream based on the predicted fluid properties. The computing system 114 can be configured to control field operations, for example, executing reactive well control, based on the calculated flow rate of the wellstream. In some embodiments, the computing system 114 may include a display device configured to present operational data related to well performance, reservoir conditions, and flow measurements.

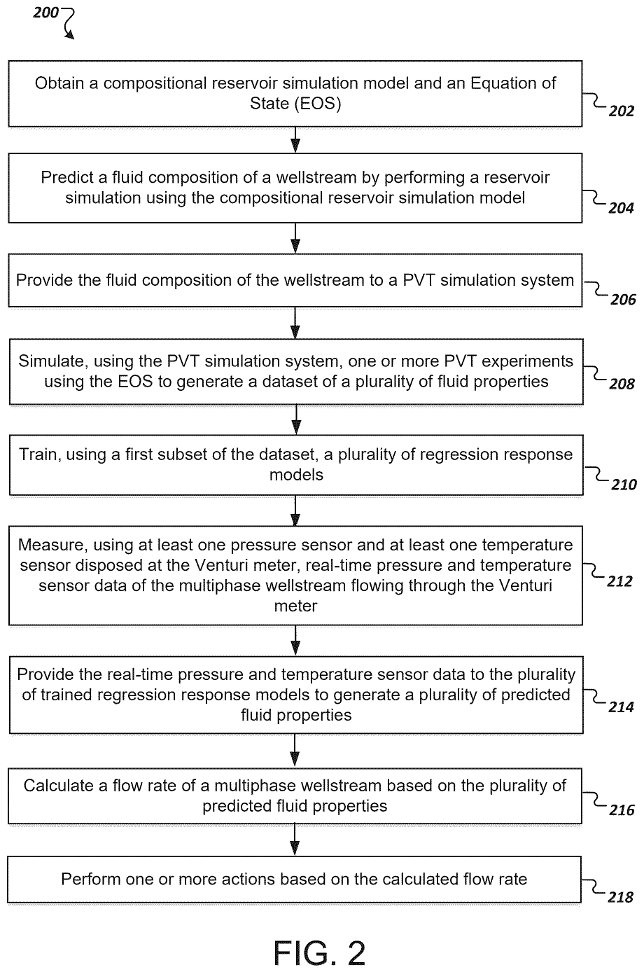

FIG. 2 is a flowchart for an example method 200 for calculating a flow rate of a multiphase wellstream through a Venturi meter using a plurality of regression response models. The method 200 can be implemented using the well system 100 in FIG. 1.

The computing system obtains 202 a compositional reservoir simulation model and an equation of state (EOS). The compositional reservoir simulation model is history-matched to accurately represent the state of the reservoir. Reservoir fluid samples are collected from the subsurface formation via the production well, and laboratory experiments are conducted on the reservoir fluid samples to determine fluid properties. The computing system 124 stores the data associated to the collected reservoir fluid samples, which includes corresponding lab-measured PVT data.

In some embodiments, the computing system 114 implements a compositional reservoir simulator system. The computing system 114 provides the data associated with the collected reservoir fluid samples, and current and historical well operating states to a compositional reservoir simulator system. The computing system 114 may further provide reservoir data that includes reservoir geometry, rock properties, and fluid properties to the compositional reservoir simulator system.

The compositional reservoir simulator system generates a history-matched compositional reservoir simulation model using the received reservoir fluid and reservoir data, and a tuned EOS. An EOS is a mathematical model that defines the relationship between pressure, volume, and temperature of the reservoir fluid, enabling the prediction of its phase behavior. The EOS can be used to calculate fluid properties (e.g., PVT parameters p_{g}, p_{c}, x_{c}) of the reservoir fluid under varying conditions. The EOS is tuned by iteratively adjusting the parameters of the EOS so that the predicted PVT parameters match the lab-measured PVT data. The EOS is tuned using data collected from the reservoir fluid samples, including associated laboratory experiment results. In some embodiments, a PVT simulation system is used to tune the EOS. The EOS used may include, but is not limited to, the Peng-Robinson EOS and the Soave-Redlich-Kwong EOS.

The compositional reservoir simulator system uses the received reservoir fluid and reservoir data and EOS to iteratively adjust model parameters so that the outputs of the reservoir simulation model match the historical data. The compositional reservoir simulator system used may include ECLIPSE, GEM, tNavigator, or any appropriate compositional reservoir simulator system.

The computing system predicts 204 a fluid composition of a wellstream by performing a reservoir simulation using the compositional reservoir simulation model. The resulting fluid composition is representative of the wellstream fluid produced by the well under prevailing operating conditions, which may include parameters such as reservoir pressure and temperature, wellbore pressure, injection and production rates, and settings on surface equipment.

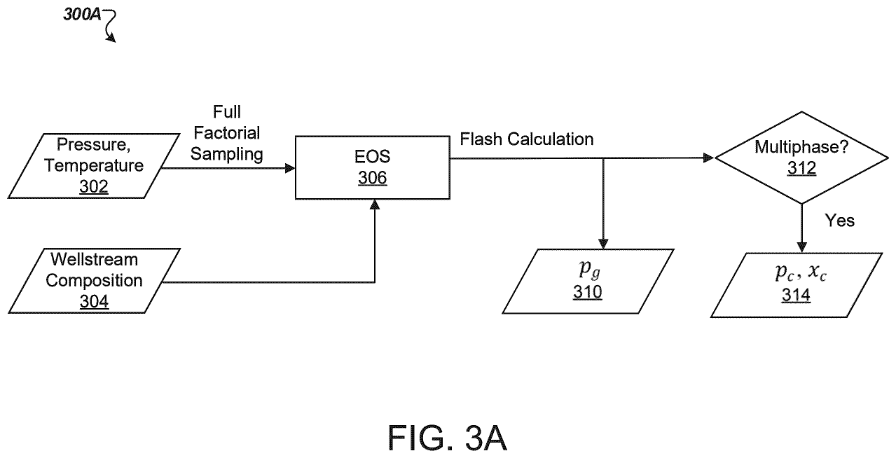

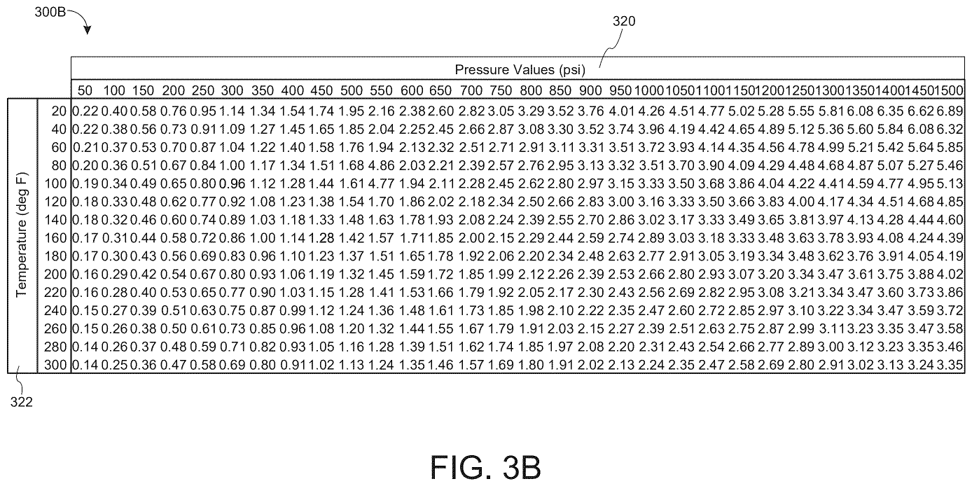

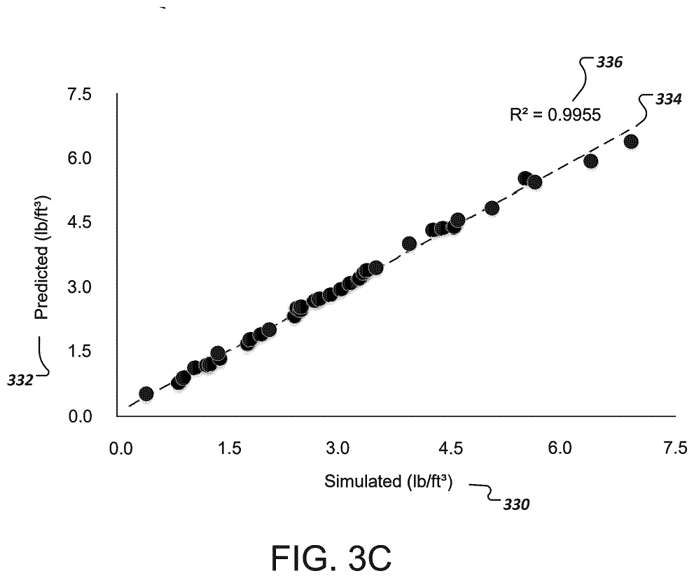

The computing system provides 206 the fluid composition of the wellstream to a PVT simulation system. The PVT simulation system simulates 208 one or more PVT experiments using the EOS to generate a dataset comprising a plurality of fluid properties. The PVT simulation system uses the tuned EOS to simulate single-stage flash experiments based on the predicted fluid composition of the wellstream to predict PVT parameters under various pressure and temperature values. The set of pressure and temperature values correspond to an expected operating range of pressure and temperature conditions at the Venturi meter and the single-stage flash experiments are conducted using a full factorial Design of Experiments (DOE) over the defined pressure and temperature range. Each simulated single-stage flash experiment of the wellstream is performed at a predetermined pressure and temperature condition to generate PVT parameters p_{g}, p_{c}, x_{c}. The computing system stores the output of each simulated single-stage flash experiment as an element in a dataset D. For example, each element of dataset D includes the fluid properties of the wellstream fluid predicted from the PVT simulation and the corresponding pressure and temperature values. This process is described in further detail with respect to FIG. 3.

The computing system implements a plurality of regression response models, each configured to predict a respective PVT parameter of the wellstream fluid based on pressure and temperature parameters, which are used to calculate the flow rate of the wellstream fluid. For example, a first regression response model is configured to predict p_{g} values, a second regression response model is configured to predict p_{c} values, and a third regression response model configured to predict x_{c} values. The computing system assembles datasets F and V by drawing elements from dataset D at random, where datasets F and V are proper subsets of dataset D, and dataset F is larger than dataset V.

The computing system trains 210, using a first subset of the dataset, a plurality of regression response models. The computing system trains each of the plurality of regression response models using dataset F to predict a respective fluid property, such as gas density, condensate density, or condensate mass fraction, based on pressure and temperature inputs.

After training the regression response models using dataset F, each model is validated using dataset V. Like dataset F, dataset V contains pressure and temperature values along with corresponding fluid property values obtained from simulated PVT experiments. The trained regression model is applied to the pressure and temperature values to generate a predicted PVT parameter p_{g}, p_{c}, x_{c} values. The predicted p_{g}, p_{c}, x_{c} values are then compared to the simulated p_{g}, p_{c}, x_{c} values generated from the PVT simulation experiments. The computing system determines that a regression response model is validated upon satisfying one or more validation criteria. The validation criteria may include, but are not limited to, a minimum coefficient of determination (R²), a maximum allowable error, or a mean squared error threshold to assess model performance. If a model fails to meet the criteria, it may be retrained using an updated or extended dataset to improve accuracy across the relevant operating conditions.

Upon validating the performance of the trained regression response models, the models can be used for real-time monitoring of the flow rate of the wellstream at the Venturi meter. The at least one pressure sensor and at least one temperature sensor disposed at the Venturi meter measures 212 real-time pressure and temperature sensor data of the multiphase wellstream flowing through the Venturi meter. The controller of the Venturi meter system receives and transmits real-time sensor data to the computing system for processing. The computing system provides 214 the real-time pressure and temperature sensor data to the plurality of trained regression response models to generate a plurality of predicted fluid properties. Each of the regression response models analyzes the real-time pressure and temperature sensor data to generate the PVT parameter p_{g}, p_{c}, and x_{c} values.

The computing system calculates 216 a flow rate of a multiphase wellstream flowing through the Venturi meter based on the plurality of predicted fluid properties. The computing system calculates the mass and volume flow rates by applying the predicted PVT parameter p_{g}, p_{c}, and x_{c} values to one or more Venturi flow equations that account for multiphase gas behavior.

The well system performs 218 one or more actions based on the calculated flow rate. The actions may include using the calculated flow rate to monitor well performance, evaluate production trends, assess reservoir behavior, or allocate production among different zones or wells. In some embodiments, the flow rate may be used to support reactive well control, such as adjusting choke settings, shutting in or opening wells, or modifying injection and withdrawal rates. In some embodiments, the computing systems may include a display device configured to present operational data, such as calculated flow rates, wellstream composition estimates, pressure and temperature measurements, regression model outputs, well performance indicators, reservoir behavior and production trends, and alerts or recommendations for well control actions. This allows operators to monitor the behavior of the wellstream and make informed decisions based on real-time data.

In some embodiments, the computing system may retrain the regression response models. The computing system may retrain the regression response models on an updated dataset D that accounts for variations, such as changes in operating conditions or changes in wellstream compositions due to well recompletion in a different reservoir zone. Retraining may be triggered when the computing system detects a significant deviation between the model-calculated flow rates and the total field rate measured at the fiscal meter.

An example implementation of the method 200 includes application to a depleted gas condensate field that is repurposed for seasonal underground gas storage. During the low gas demand season, excess gas supply available on the gas distribution network is withdrawn from the network and injected underground into the depleted reservoir for storage. During the high gas demand season, shortfalls in gas supply available from the rest of the gas network will be made up by withdrawing gas from the underground storage into the gas distribution network. The method 200 can be used to obtain p_{g}, p_{c}, and x_{c} regression response models for Venturi multiphase flow metering during the first withdrawal period. During this phase, the production wellstream composition is not only dissimilar to the depletion-phase fluid but is also rapidly changing. As a result, lab-measured PVT data may no longer accurately represent the behavior of the current fluid mixture.

FIG. 3A is a flowchart that represents an example PVT experiment 300A executed by a PVT simulation system to generate a dataset of fluid properties under various operating conditions. As described in FIG. 2, the PVT simulation system executes simulated PVT experiments to generate a dataset comprising a plurality of fluid properties, including PVT parameters p_{g}, p_{c}, and x_{c}. The PVT simulation system accesses a pressure and temperature dataset comprising pressure and temperature values that correspond to the expected operating range of the Venturi meter. The PVT simulation system receives the wellstream composition 304, predicted by the history-matched compositional reservoir simulation model.

The PVT simulation system provides pressure and temperature values to the EOS 306 based on a DOE approach, using full factorial sampling to generate combinations of pressure and temperature values from the pressure and temperature dataset. For example, for each PVT experiment 300A, the PVT simulation system provides a unique combination of pressure and temperature values to the EOS 306 to generate predicted PVT parameters. This enables the PVT simulation system to systematically generate predicted PVT parameters for all possible combinations of pressure and temperature values in the pressure temperature dataset.

For each PVT experiment 300A, the EOS 306 receives a combination of pressure and temperature values 302 and the wellstream composition 304 as input. The PVT simulation system performs a single-stage flash experiment using the EOS 306 to simulate the phase behavior of the wellstream for the received combination of pressure and temperature values. The PVT simulation system determines whether the wellstream is single-phase or multiphase 312 based on the results of the single-stage flash experiment. If the result of the single-stage flash calculation indicates that the wellstream is single-phase, the PVT simulation system stores the generated gas density value 310, p_{g}, in dataset D. In response to determining that the wellstream is multiphase, the PVT simulation system stores additional generated parameters, including the condensate density value, p_{c}, and the condensate mass fraction value 314, x_{c}, in dataset D. The PVT simulation system stores the PVT parameter values in association with their corresponding pressure and temperature values 302 in dataset D. Upon completing the plurality of PVT experiments, the dataset D is populated with PVT parameters encompassing the range of pressure and temperature conditions. Dataset D is then used to train regression response models that predict PVT parameters in real time, enabling accurate Venturi-based flowrate estimation under varying field conditions.

FIG. 3B is a table 300B that represents example gas densities obtained from simulated PVT experiments. The table presents gas density values, p_{g}, in pounds per cubic foot (lb/ft³), generated by the PVT simulation system across a range of pressure and temperature conditions corresponding to the expected operating range of the Venturi meter. The table includes two dimensions, pressure values 320 and temperature 322. The horizontal dimension corresponds to pressure values (in psi) 320, ranging from 50 psi to 1500 psi. The vertical dimension corresponds to temperature values (in degrees Fahrenheit) 322, ranging from 20 °F to 300 °F. Each cell in the table represents the p_{g} value predicted by a single-stage flash experiment for a unique combination of pressure and temperature.

In the illustrated example, the results from 407 out of the 450 experiments (e.g., approximately 90% of the total) may be used to train a regression response model to predict p_{g} values. In some embodiments, the p_{g} values used to train the regression response model were randomly selected. The results of the remaining 43 experiments may be used for validating the regression response model.

FIG. 3C is a plot 300C that illustrates the validation of a gas density (e.g., p_{g}) regression response model against simulated PVT experiment results. In the illustrated example, the plot 300C compares the predicted p_{g} values generated by the regression response model against the simulated p_{g} values generated by PVT experiments, for a validation dataset comprising 43 experiments. The x-axis represents the simulated p_{g} values 330 (in lb/ft³), while the y-axis represents the corresponding predicted p_{g} values 332 generated by the regression response model. Each dot represents a predicted p_{g} value plotted against the corresponding simulated p_{g} value. The dashed trendline 334 provides a visual indication of the correlation between predicted and simulated values. The close alignment of the data points with the dashed trendline 334 demonstrates that the regression response model produces predicted values that closely match the simulated values. The coefficient of determination (e.g., R²) 336 value of 0.9955 indicates the regression response model accurately predicts p_{g} over the range of simulated conditions.

The high degree of alignment between the predicted and simulated values demonstrates the reliability and accuracy of the p_{g} regression response model. A similar training and validation process is performed for the condensate density p_{c} and condensate mass fraction x_{c} regression response models. However, for the p_{c} and x_{c} regression response models, only the subset of simulated PVT experiments that indicated multiphase conditions was used for training and validation.

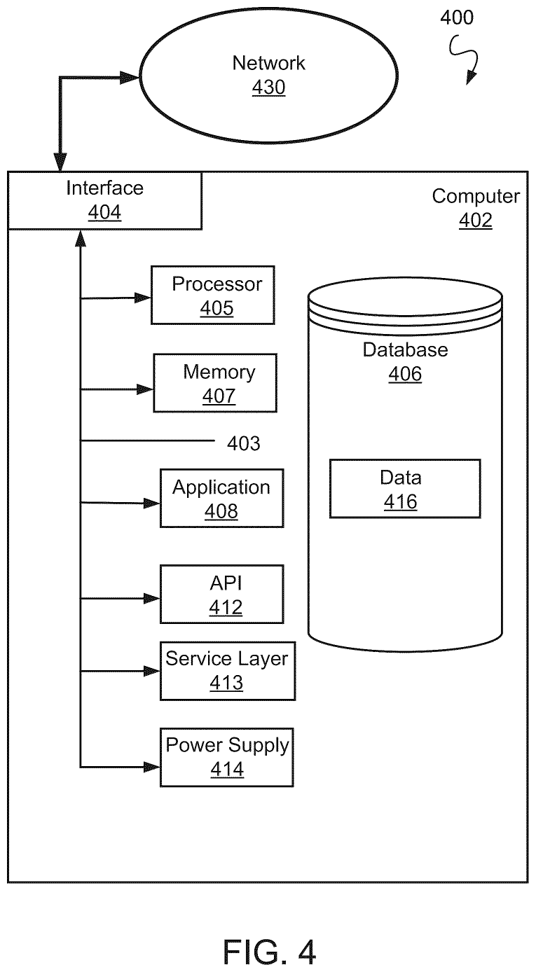

FIG. 4 is a block diagram of an example computer system 400 used to provide computational functionalities associated with described algorithms, methods, functions, processes, flows, and procedures described in the present disclosure, according to some implementations of the present disclosure. The illustrated computer 402 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 402 can include input devices such as keypads, keyboards, and touch screens that can accept user information. Also, the computer 402 can include output devices that can convey information associated with the operation of the computer 402. The information can include digital data, visual data, audio information, or a combination of information. The information can be presented in a graphical user interface (UI) (or GUI).

The computer 402 can serve in a role as a client, a network component, a server, a database, a persistency, or components of a computer system for performing the subject matter described in the present disclosure. The illustrated computer 402 is communicably coupled with a network 430. In some implementations, one or more components of the computer 402 can be configured to operate within different environments, including cloud-computing-based environments, local environments, global environments, and combinations of environments.

At a high level, the computer 402 is an electronic computing device operable to receive, transmit, process, store, and manage data and information associated with the described subject matter. According to some implementations, the computer 402 can also include, or be communicably coupled with, an application server, an email server, a web server, a caching server, a streaming data server, or a combination of servers.

The computer 402 can receive requests over network 430 from a client application (for example, executing on another computer 402). The computer 402 can respond to the received requests by processing the received requests using software applications. Requests can also be sent to the computer 402 from internal users (for example, from a command console), external (or third) parties, automated applications, entities, individuals, systems, and computers.

Each of the components of the computer 402 can communicate using a system bus 403. In some implementations, any, or all of the components of the computer 402, including hardware or software components, can interface with each other or the interface 404 (or a combination of both), over the system bus 403. Interfaces can use an application programming interface (API) 412, a service layer 413, or a combination of the API 412 and service layer 413. The API 412 can include specifications for routines, data structures, and object classes. The API 412 can be either computer-language independent or dependent. The API 412 can refer to a complete interface, a single function, or a set of APIs.

The service layer 413 can provide software services to the computer 402 and other components (whether illustrated or not) that are communicably coupled to the computer 402. The functionality of the computer 402 can be accessible for all service consumers using this service layer. Software services, such as those provided by the service layer 413, can provide reusable, defined functionalities through a defined interface. For example, the interface can be software written in JAVA, C++, or a language providing data in extensible markup language (XML) format. While illustrated as an integrated component of the computer 402, in alternative implementations, the API 412 or the service layer 413 can be stand-alone components in relation to other components of the computer 402 and other components communicably coupled to the computer 402. Moreover, any or all parts of the API 412 or the service layer 413 can be implemented as child or sub-modules of another software module, enterprise application, or hardware module without departing from the scope of the present disclosure.

The computer 402 includes an interface 404. Although illustrated as a single interface 404 in FIG. 4, two or more interfaces 404 can be used according to particular needs, desires, or particular implementations of the computer 402 and the described functionality. The interface 404 can be used by the computer 402 for communicating with other systems that are connected to the network 430 (whether illustrated or not) in a distributed environment. Generally, the interface 404 can include, or be implemented using, logic encoded in software or hardware (or a combination of software and hardware) operable to communicate with the network 430. More specifically, the interface 404 can include software supporting one or more communication protocols associated with communications. As such, the network 430 or the interface's hardware can be operable to communicate physical signals within and outside of the illustrated computer 402.

The computer 402 includes a processor 405. Although illustrated as a single processor 405 in FIG. 4, two or more processors 405 can be used according to particular needs, desires, or particular implementations of the computer 402 and the described functionality. Generally, the processor 405 can execute instructions and can manipulate data to perform the operations of the computer 402, including operations using algorithms, methods, functions, processes, flows, and procedures as described in the present disclosure.

The computer 402 also includes a database 406 that can hold data for the computer 402 and other components connected to the network 430 (whether illustrated or not). For example, database 406 can hold data 416. For example, database 406 can be an in-memory, conventional, or a database storing data consistent with the present disclosure. In some implementations, database 406 can be a combination of two or more different database types (for example, hybrid in-memory and conventional databases) according to particular needs, desires, or particular implementations of the computer 402 and the described functionality. Although illustrated as a single database 406 in FIG. 4, two or more databases (of the same, different, or combination of types) can be used according to particular needs, desires, or particular implementations of the computer 402 and the described functionality. While database 406 is illustrated as an internal component of the computer 402, in alternative implementations, database 406 can be external to the computer 402.

The computer 402 also includes a memory 407 that can hold data for the computer 402 or a combination of components connected to the network 430 (whether illustrated or not). Memory 407 can store any data consistent with the present disclosure. In some implementations, memory 407 can be a combination of two or more different types of memory (for example, a combination of semiconductor and magnetic storage) according to particular needs, desires, or particular implementations of the computer 402 and the described functionality. Although illustrated as a single memory 407 in FIG. 4, two or more memories 407 (of the same, different, or combination of types) can be used according to particular needs, desires, or particular implementations of the computer 402 and the described functionality. While memory 407 is illustrated as an internal component of the computer 402, in alternative implementations, memory 407 can be external to the computer 402.

The application 408 can be an algorithmic software engine providing functionality according to particular needs, desires, or particular implementations of the computer 402 and the described functionality. For example, application 408 can serve as one or more components, modules, or applications. Further, although illustrated as a single application 408, the application 408 can be implemented as multiple applications 408 on the computer 402. In addition, although illustrated as internal to the computer 402, in alternative implementations, the application 408 can be external to the computer 402.

The computer 402 can also include a power supply 414. The power supply 414 can include a rechargeable or non-rechargeable battery that can be configured to be either user-or non-user-replaceable. In some implementations, the power supply 414 can include power-conversion and management circuits, including recharging, standby, and power management functionalities. In some implementations, the power-supply 414 can include a power plug to allow the computer 402 to be plugged into a wall socket or a power source to, for example, power the computer 402 or recharge a rechargeable battery.

There can be any number of computers 402 associated with, or external to, a computer system containing computer 402, with each computer 402 communicating over network 430. Further, the terms “client,” “user,” and other appropriate terminology can be used interchangeably, as appropriate, without departing from the scope of the present disclosure. Moreover, the present disclosure contemplates that many users can use one computer 402 and one user can use multiple computers 402.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware-or software-based (or a combination of both hardware-and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example LINUX, UNIX, WINDOWS, MAC OS, ANDROID, or IOS.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

A number of implementations of these systems and methods have been described. Nevertheless, it will be understood that various modifications may be made without departing from the spirit and scope of this disclosure. Accordingly, other implementations are within the scope of the following claims.

### EXAMPLES

In an example implementation, a method for calculating a flow rate of a multiphase wellstream through a Venturi meter, the method comprising: obtaining a compositional reservoir simulation model and an equation of state (EOS); predicting a fluid composition of a wellstream by performing a reservoir simulation using the compositional reservoir simulation model; providing the fluid composition of the wellstream to a PVT simulation system; simulating, using the PVT simulation system, one or more PVT experiments using the EOS to generate a dataset of a plurality of fluid properties based on the wellstream fluid composition; training, using a first subset of the dataset, a plurality of regression response models, wherein each of the regression response models is trained to predict a respective fluid property from the plurality of fluid properties; measuring, using at least one pressure sensor and at least one temperature sensor disposed at the Venturi meter, real-time pressure and temperature sensor data of the multiphase wellstream flowing through the Venturi meter; providing the real-time pressure and temperature sensor data to the plurality of trained regression response models to generate a plurality of predicted fluid properties; calculating a flow rate of a multiphase wellstream based on the plurality of predicted fluid properties; and performing one or more actions based on the calculated flow rate.

In an aspect combinable with the example implementation, wherein the compositional reservoir simulation model and the EOS are obtained based on reservoir PVT fluid samples and associated laboratory conducted PVT experiments.

In another aspect combinable with the example implementation, wherein the plurality of fluid properties comprises gas density, condensate density, and condensate mass fraction.

In another aspect combinable with the example implementation, wherein the reservoir simulation is performed using the compositional reservoir simulation model with the EOS, wherein the EOS is one of Peng-Robinson or Soave-Redlich-Kwong.

In another aspect combinable with the example implementation, wherein the one or more PVT experiments comprise single-stage flash experiments of the wellstream fluid.

In another aspect combinable with the example implementation, further comprising validating the regression response models using a second subset of the dataset, wherein the first subset and the second subset are proper subsets, the validating comprising: applying each trained regression response model to pressure and temperature values from the second subset of the dataset to generate corresponding predicted fluid property values; comparing the predicted fluid property values to corresponding fluid property values obtained from the one or more PVT experiments; and determining whether each regression response model satisfies one or more validation criteria.

In an example implementation, a system for calculating a flow rate of a multiphase wellstream through a Venturi meter. The system comprises a venturi meter system comprising: a Venturi meter configured to direct the multiphase wellstream through its body; at least one pressure sensor disposed at the Venturi meter and configured to capture pressure data of the multiphase wellstream; and at least one temperature sensor disposed at the Venturi meter and configured to capture temperature data of the multiphase wellstream. The system further comprises a computing device comprising at least one processor and a memory storing instructions, that when executed by the at least one processor, cause the at least one processor to perform operations comprising: obtaining a compositional reservoir simulation model and an equation of state (EOS); predicting a fluid composition of a wellstream by performing a reservoir simulation using the compositional reservoir simulation model; providing the fluid composition of the wellstream to a PVT simulation system; simulating, using the PVT simulation system, one or more PVT experiments using the EOS to generate a dataset of a plurality of fluid properties based on the wellstream fluid composition; training, using a first subset of the dataset, a plurality of regression response models, wherein each of the regression response models is trained to predict a respective fluid property from the plurality of fluid properties; measuring, using at least one pressure sensor and at least one temperature sensor disposed at the Venturi meter, real-time pressure and temperature sensor data of the multiphase wellstream flowing through the Venturi meter; providing the real-time pressure and temperature sensor data to the plurality of trained regression response models to generate a plurality of predicted fluid properties; calculating a flow rate of a multiphase wellstream based on the plurality of predicted fluid properties; and performing one or more actions based on the calculated flow rate.

In an aspect combinable with the example implementation, wherein the compositional reservoir simulation model and the EOS are obtained based on reservoir PVT fluid samples and associated laboratory conducted PVT experiments.

In another aspect combinable with the example implementation, wherein the plurality of fluid properties comprises gas density, condensate density, and condensate mass fraction.

In another aspect combinable with the example implementation, wherein the reservoir simulation is performed using the compositional reservoir simulation model with the EOS, wherein the EOS is one of Peng-Robinson or Soave-Redlich-Kwong.

In another aspect combinable with the example implementation, wherein the one or more PVT experiments comprise single-stage flash experiments of the wellstream fluid.

In another aspect combinable with the example implementation, the operations further comprise validating the regression response models using a second subset of the dataset, wherein the first subset and the second subset are proper subsets, the validating comprising: applying each trained regression response model to pressure and temperature values from the second subset of the dataset to generate corresponding predicted fluid property values; comparing the predicted fluid property values to corresponding fluid property values obtained from the one or more PVT experiments; and determining whether each regression response model satisfies one or more validation criteria.

In another aspect combinable with the example implementation, wherein the one or more actions comprise adjusting well control parameters.

In another example implementation, one or more non-transitory non-transitory computer-readable mediums storing instructions for calculating a flow rate of a multiphase wellstream flowing through a Venturi meter, the instructions being executable by one or more processors to cause performance of operations comprising: obtaining a compositional reservoir simulation model and an equation of state (EOS); predicting a fluid composition of a wellstream by performing a reservoir simulation using the compositional reservoir simulation model; providing the fluid composition of the wellstream to a PVT simulation system; simulating, using the PVT simulation system, one or more PVT experiments using the EOS to generate a dataset of a plurality of fluid properties based on the wellstream fluid composition; training, using a first subset of the dataset, a plurality of regression response models, wherein each of the regression response models is trained to predict a respective fluid property from the plurality of fluid properties; measuring, using at least one pressure sensor and at least one temperature sensor disposed at the Venturi meter, real-time pressure and temperature sensor data of the multiphase wellstream flowing through the Venturi meter; providing the real-time pressure and temperature sensor data to the plurality of trained regression response models to generate a plurality of predicted fluid properties; calculating a flow rate of a multiphase wellstream based on the plurality of predicted fluid properties; and performing one or more actions based on the calculated flow rate.

In another aspect combinable with the example implementation, wherein the plurality of fluid properties comprises gas density, condensate density, and condensate mass fraction.

In another aspect combinable with the example implementation, wherein the reservoir simulation is performed using the compositional reservoir simulation model with the EOS, wherein the EOS is one of Peng-Robinson or Soave-Redlich-Kwong.

In another aspect combinable with the example implementation, wherein the one or more PVT experiments comprise single-stage flash experiments of the wellstream fluid.

In another aspect combinable with the example implementation, the operations further comprise validating the regression response models using a second subset of the dataset, wherein the first subset and the second subset are proper subsets, the validating comprising: applying each trained regression response model to pressure and temperature values from the second subset of the dataset to generate corresponding predicted fluid property values; comparing the predicted fluid property values to corresponding fluid property values obtained from the one or more PVT experiments; and determining whether each regression response model satisfies one or more validation criteria.

In another aspect combinable with the example implementation, wherein the one or more actions comprise adjusting well control parameters.

What is claimed is:

1. A method for calculating a flow rate of a multiphase wellstream flowing through a Venturi meter, the method comprising:
obtaining a compositional reservoir simulation model and an equation of state (EOS);
predicting a fluid composition of a wellstream by performing a reservoir simulation using the compositional reservoir simulation model;
providing the fluid composition of the wellstream to a PVT simulation system;
simulating, using the PVT simulation system, one or more PVT experiments using the EOS to generate a dataset of a plurality of fluid properties based on the fluid composition of the wellstream, wherein each element of the dataset includes a set of fluid properties and corresponding pressure and temperature values;
training, using a first subset of the dataset, a plurality of regression response models, wherein each of the regression response models is trained to predict a respective fluid property based on pressure and temperature values;
measuring, using at least one pressure sensor and at least one temperature sensor disposed at the Venturi meter, real-time pressure and temperature sensor data of the multiphase wellstream flowing through the Venturi meter;
providing the real-time pressure and temperature sensor data to the plurality of trained regression response models to generate a plurality of predicted fluid properties;
calculating a flow rate of a multiphase wellstream based on the plurality of predicted fluid properties; and
performing one or more actions based on the calculated flow rate.

2. The method of claim 1, wherein the compositional reservoir simulation model and the EOS are obtained based on reservoir PVT fluid samples and associated laboratory conducted PVT experiments.

3. The method of claim 1, wherein the plurality of fluid properties comprises gas density, condensate density, and condensate mass fraction.

4. The method of claim 1, wherein the reservoir simulation is performed using the compositional reservoir simulation model with the EOS, wherein the EOS is one of Peng-Robinson or Soave-Redlich-Kwong.

5. The method of claim 1, wherein the one or more PVT experiments comprise single-stage flash simulation experiments performed based on the fluid composition of the multiphase wellstream.

6. The method of claim 1, further comprising validating the regression response models using a second subset of the dataset, wherein the first subset and the second subset are proper subsets, the validating comprising:
applying each trained regression response model to pressure and temperature values from the second subset of the dataset to generate corresponding predicted fluid property values;
comparing the predicted fluid property values to corresponding fluid property values obtained from the one or more PVT experiments; and
determining whether each regression response model satisfies one or more validation criteria.

7. The method of claim 1, wherein the one or more actions comprise adjusting well control parameters.

8. A system for calculating a flow rate of a multiphase wellstream flowing through a Venturi meter, the system comprising:
a venturi meter system comprising:
a Venturi meter configured to direct the multiphase wellstream through its body;
at least one pressure sensor disposed at the Venturi meter and configured to capture pressure data of the multiphase wellstream; and
at least one temperature sensor disposed at the Venturi meter and configured to capture temperature data of the multiphase wellstream; and
a computing device comprising at least one processor and a memory storing instructions, that when executed by the at least one processor, cause the at least one processor to perform operations comprising:
obtaining a compositional reservoir simulation model and an equation of state (EOS);
predicting a fluid composition of a wellstream by performing a reservoir simulation using the compositional reservoir simulation model;
providing the fluid composition of the wellstream to a PVT simulation system;
simulating, using the PVT simulation system, one or more PVT experiments using the EOS to generate a dataset of a plurality of fluid properties based on the fluid composition of the wellstream, wherein each element of the dataset includes a set of fluid properties and corresponding pressure and temperature values;
training, using a first subset of the dataset, a plurality of regression response models, wherein each of the regression response models is trained to predict a respective fluid property based on pressure and temperature values;
measuring, using the at least one pressure sensor and the at least one temperature sensor, real-time pressure and temperature sensor data of the multiphase wellstream flowing through the Venturi meter;
providing the real-time pressure and temperature sensor data to the plurality of trained regression response models to generate a plurality of predicted fluid properties;
calculating a flow rate of a multiphase wellstream based on the plurality of predicted fluid properties; and
performing one or more actions based on the calculated flow rate.

9. The system of claim 8, wherein the compositional reservoir simulation model and the EOS are obtained based on reservoir PVT fluid samples and associated laboratory conducted PVT experiments.

10. The system of claim 8, wherein the plurality of fluid properties comprises gas density, condensate density, and condensate mass fraction.

11. The system of claim 8, wherein the reservoir simulation is performed using the compositional reservoir simulation model with the EOS, wherein the EOS is one of Peng-Robinson or Soave-Redlich-Kwong.

12. The system of claim 8, wherein the one or more PVT experiments comprise single-stage flash simulation experiments performed based on the fluid composition of the multiphase wellstream.

13. The system of claim 8, wherein the operations further comprise validating the regression response models using a second subset of the dataset, wherein the first subset and the second subset are proper subsets, the validating comprising:
applying each trained regression response model to pressure and temperature values from the second subset of the dataset to generate corresponding predicted fluid property values;
comparing the predicted fluid property values to corresponding fluid property values obtained from the one or more PVT experiments; and
determining whether each regression response model satisfies one or more validation criteria.

14. The system of claim 8, wherein the one or more actions comprise adjusting well control parameters.

15. One or more non-transitory machine-readable storage devices storing instructions for calculating a flow rate of a multiphase wellstream flowing through a Venturi meter, the instructions being executable by one or more processors to cause performance of operations comprising:
obtaining a compositional reservoir simulation model and an equation of state (EOS);
predicting a fluid composition of a wellstream by performing a reservoir simulation using the compositional reservoir simulation model;
providing the fluid composition of the wellstream to a PVT simulation system;
simulating, using the PVT simulation system, one or more PVT experiments using the EOS to generate a dataset of a plurality of fluid properties based on the fluid composition of the wellstream, wherein each element of the dataset includes a set of fluid properties and corresponding pressure and temperature values;
training, using a first subset of the dataset, a plurality of regression response models, wherein each of the regression response models is trained to predict a respective fluid property based on pressure and temperature values;
measuring, using at least one pressure sensor and at least one temperature sensor disposed at the Venturi meter, real-time pressure and temperature sensor data of the multiphase wellstream flowing through the Venturi meter;
providing the real-time pressure and temperature sensor data to the plurality of trained regression response models to generate a plurality of predicted fluid properties;
calculating a flow rate of a multiphase wellstream based on the plurality of predicted fluid properties; and
performing one or more actions based on the calculated flow rate.

16. The one or more non-transitory machine-readable storage devices of claim 15, wherein the plurality of fluid properties comprises gas density, condensate density, and condensate mass fraction.

17. The one or more non-transitory machine-readable storage devices of claim 15, wherein the reservoir simulation is performed using the compositional reservoir simulation model with the EOS, wherein the EOS is one of Peng-Robinson or Soave-Redlich-Kwong.

18. The one or more non-transitory machine-readable storage devices of claim 15, wherein the one or more PVT experiments comprise single-stage flash simulation experiments performed based on the fluid composition of the multiphase wellstream.

19. The one or more non-transitory machine-readable storage devices of claim 15, wherein the operations further comprise validating the regression response models using a second subset of the dataset, wherein the first subset and the second subset are proper subsets, the validating comprising:
applying each trained regression response model to pressure and temperature values from the second subset of the dataset to generate corresponding predicted fluid property values;
comparing the predicted fluid property values to corresponding fluid property values obtained from the one or more PVT experiments; and
determining whether each regression response model satisfies one or more validation criteria.

20. The one or more non-transitory machine-readable storage devices of claim 15, wherein the one or more actions comprise adjusting well control parameters.
